(19) United States
(12) Patent Application Publication
(10) Pub. No.: US 2009/0263948 A1
(43) Pub. Date: Oct. 22, 2009

(54) METAL OXIDE SEMICONDUCTOR FIELD-EFFECT TRANSISTOR (MOSFET) AND METHOD OF FABRICATING THE SAME

(76) Inventor: Myoung-Soo KIM, Suwon-si (KR)

Correspondence Address: F. CHAU & ASSOCIATES, LLC, 130 WOODBURY ROAD, WOODBURY, NY, 11797, US

(21) Appl. No.: 12/498,000

(22) Filed: Jul. 6, 2009

Related U.S. Application Data
(62) Division of application No. 11/443,385, filed on May 30, 2006.

(30) Foreign Application Priority Data
Jun. 8, 2005 (KR) 2005-0048820

(51) Int. Cl. H01L 21/8234; H01L 21/336

(52) U.S. Cl. 438/275; 438/294; 257/E21.616; 257/E21.409

(57) ABSTRACT

A Metal Oxide Semiconductor Field-Effect Transistor (MOSFET) is provided. The MOSFET includes a semiconductor substrate, a device isolating region disposed on a predetermined portion of the semiconductor substrate to define an active region, a source region and a drain region spaced apart from each other about a channel region within the active region, and a gate electrode formed on the active region between the source region and the drain region. Furthermore, the MOSFET also includes a gate insulating layer formed between the active region and the gate electrode. The gate insulating layer includes a central gate insulating layer disposed under central portion of the gate electrode, an edge gate insulating layer disposed under an edge portion of the gate electrode to have a bottom surface level with a bottom of the central gate insulating layer and an upper surface protruding to be higher than an upper surface of the central gate insulating layer.

### CROSS-REFERENCE TO RELATED PATENT APPLICATION

This application is a divisional of application Ser. No. 11/443,385, filed May 30, 2006 which claims the priority under 35 U.S.C. §119 to Korean Patent Application No. 10-2005-0048820, filed on Jun. 8, 2005, in the Korean Intellectual Property Office, the disclosures of which are each incorporated by reference herein in their entireties.

### BACKGROUND OF THE INVENTION

1. Field of the Invention

The present invention relates to a semiconductor device and a method of fabricating the same, and more particularly to a Metal Oxide Semiconductor (MOS) transistor with a decreased leakage current for the transistor, and a method of fabricating the same.

2. Description of the Related Art

When fabricating an electric power device such as a Liquid Crystal Display (LCD) Driver IC (“referred to as an LDI”) in a semiconductor IC, a dual gate oxide film is typically employed since a low voltage transistor for logic operated by a low voltage and a transistor for driving an LCD operated by a high voltage should both be embodied together on the same semiconductor substrate. Furthermore, as the increased packing density of a semiconductor IC decreases linewidth, trench isolation techniques are thus applied in a device isolating region. For example, in a Shallow Trench Isolation (STI) structure provided by a trench technique, a film material used for gap fill is not a thermal oxide layer but an undoped silicate glass (USG) layer or a CVD oxide layer such as High Density Plasma (HDP)-CVD oxide layer.

A thermal oxide layer is generally used as a gate oxide layer. However, when thermal oxidation is performed for the gate oxide layer in the STI structure, a thinning of the oxide layer on an upper edge of the trench-etched STI structure occurs due to the following: (i) a compressive stress incited on a silicon substrate due to oxidation carried out on a surface of the silicon substrate and a sidewall of the STI structure, (ii) a stress of a gap fill layer of the STI structure, and (iii) an interruption to the flow of an oxidation reaction gas caused by a liner formed within the STI structure.

The above mentioned thinning phenomenon becomes even more pronounced when a process at a high withstand voltage is performed, e.g., when a thick gate oxide layer is formed to embody a high voltage transistor. Consequently, the above-mentioned thinning increases generation of double hump and a Gate Induced Drain Leakage current (GIDL) induced from a gate due to concentration of an electric field at the thinned oxide layer portion. The above-mentioned thinning process also results in the operating voltage of the transistor being restricted from increasing to a value greater than about 20 to about 30V.

Conventional techniques for fabricating a high voltage (HV) transistor and which seek to remedy the above operating voltage difficulties, include forming a thick field oxide layer on a lower portion of a gate electrode using a Local Oxidation of Silicon (LOCOS) process to alleviate the concentration of an electric field generated from the lower portion of the gate electrode, thereby embodying a transistor with a withstand voltage of about 45V. However, if an STI structure is formed on the lower portion of a gate electrode, certain difficulties may still be arise with the above conventional techniques.

For example, as illustrated in FIGS. 1 and 2, when a high voltage transistor is fabricated using the device isolation of the STI structure, the device isolating region adopts the STI structure and the field oxide is applied on a lower portion of the gate electrode via LOCOS. FIG. 1 is a layout of a conventional high voltage transistor, and FIG. 2 is a sectional view taken along line A-A′ of FIG. 1.

Referring to FIGS. 1 and 2, an active region 108 defined by a device isolating region 107 is formed within a specific region of the semiconductor substrate 100. The device isolating region 107 has a STI structure formed using a typical trench technique. Source/drain regions 104 spaced apart from each other are formed within the active region 108. A channel region is formed between the source/drain regions 104. A gate electrode 101 is formed on the channel region. In addition, a gate insulating layer is interposed between the gate electrode 101 and the channel region of the semiconductor substrate 100. The gate insulating layer is composed of a thin gate insulating layer 105 formed under the central portion of the gate electrode 101 and a thick gate insulating layer that is a field oxide layer 103 formed under an edge portion of the gate electrode 101. Moreover, the thick gate insulating layer is composed of the field oxide layer 103 formed using LOCOS. High density regions 102 doped with an impurity ion of which the density is higher than the densities of the source/drain regions 104 are formed within portions of the source/drain regions 104 where source/drain contacts 109 will be formed in a subsequent process.

The above described resultant structure is a Field Lightly Doped Drain (FLDD) structure typically used for a high voltage transistor. Moreover, with the above structure, after an ion is implanted at a low density to a portion where the field oxide layer 103 will be formed, an annealing process is then performed before forming the field oxide layer to form a grade junction. Then, the thick field oxide layer is formed. Accordingly, a strong electric field imposed upon the gate electrode 101 is alleviated by the field oxide layer 103, so that the FLDD may be applied to products requiring a high voltage of 20 to 50V or so.

However, the above-stated conventional technique involves the burdensome processing of implanting an impurity ion at a low density before forming the field oxide layer 103 in order to reinforce a junction breakdown voltage on the lower portion of the field oxide layer 103. Moreover, LOCOS applied with a wet process is employed to thus complicate the processing. Furthermore, it is also difficult to use the above-mentioned conventional techniques to control the thickness and the length of the field oxide layer 103 which functions as a gate insulating layer.

Thus, there is a need for a MOSFET, wherein the leakage current of the transistor is decreased in comparison to conventional MOSFET devices, and to method of fabricating the same.

### SUMMARY OF THE INVENTION

According to an exemplary embodiment of the present invention, a Metal Oxide Semiconductor Field-Effect Transistor (MOSFET) is provided. The MOSFET includes a semiconductor substrate, a device isolating region disposed on a predetermined portion of the semiconductor substrate to define an active region, a source region and a drain region spaced apart from each other about a channel region within the active region, and a gate electrode formed on the active region between the source region and the drain region. Furthermore, the MOSFET also includes a gate insulating layer formed between the active region and the gate electrode. The gate insulating layer includes a central gate insulating layer disposed under a central portion of the gate electrode, an edge gate insulating layer disposed under an edge portion of the gate electrode to have a bottom surface level with a bottom of the central gate insulating layer and an upper surface protruding to be higher than an upper surface of the central gate insulating layer.

Here, the edge gate insulating layer may comprise a plurality of layers, and the uppermost layer of the edge gate insulating layer and the central gate insulating layer are composed of the same material. Moreover, the edge gate insulating layer extends to the entire surface of the source region and the drain region, and the device isolating region has a Shallow Trench Isolation (STI) structure.

According to another exemplary embodiment of the present invention, a method of fabricating a Metal Oxide Semiconductor Field-Effect Transistor (MOSFET) is provided. The method includes forming a device isolating region in a predetermined portion of a semiconductor substrate to define an active region, forming a source region and a drain region spaced apart from each other within the active region, forming a first insulating layer pattern to expose a channel region disposed between the source region and the drain region, and forming a second insulating layer is on at least substantially the entire surface of the semiconductor substrate having the first insulating layer pattern thereon. The method further includes forming a gate electrode overlapping at least part of the source region and the drain region stacked with the first insulating layer pattern and the second insulating layer. The gate electrode formed also overlaps at least part of the channel region formed with the second insulating layer thereon.

In addition, before forming the gate electrode, the first insulating layer pattern and the second insulating layer may be partially removed to expose a surface of the semiconductor substrate where a source contact and a drain contact will be formed within the source region and the drain region. Then, a third insulating layer is formed on the exposed surface of the semiconductor substrate. Additionally, after forming the gate electrode, high density regions with an ion density higher than those of the source region and the drain region are formed within the semiconductor substrate where the source contact and the drain contact will be formed.

According to another exemplary embodiment of the present invention, a method of fabricating a Metal Oxide Semiconductor Field-Effect Transistor (MOSFET) is provided. The Method includes forming a device isolating region in a predetermined portion of a semiconductor substrate for defining a first active region formed with a high voltage transistor and a second active region formed with a low voltage transistor, forming a first source region and a first drain region spaced apart from each other within the first active region, forming a first insulating layer on at least substantially the entire surface of the semiconductor substrate, and then etching the first insulating layer to form a first insulating layer pattern that exposes a channel region disposed between the first source region and the second drain region. Subsequently, a second insulating layer is formed on at least substantially the entire surface of the semiconductor substrate formed with the first insulating layer pattern thereon. Thereafter, the first insulating layer pattern and the second insulating layer formed on the second active region are removed. The method further includes forming a gate electrode material on at least substantially the entire surface of the semiconductor substrate and then etching the gate electrode material to form a first gate electrode that overlaps at least part of the first source region and the first drain region stacked with the first insulating layer pattern and the second insulating layer. The gate electrode formed also overlaps at least part of the channel region formed with the second insulating layer thereon.

Additionally, when removing the first insulating layer pattern and the second insulating layer formed on the second active region, the first insulating layer pattern and the second insulating layer within the first active region may be partially removed to expose the surface of the semiconductor substrate where the source contact and the drain contact are formed within the first source region and the first drain region. Then, before forming the first gate electrode, a third insulating layer is formed on the surface of the exposed semiconductor substrate.

When forming the first gate electrode, a second gate electrode may be simultaneously formed on the third insulating layer disposed on the second active region. Also, after forming the second gate electrode, a second source region and a second drain region may be formed within the semiconductor substrate on the lower portions of both sidewalls of the second gate electrode.

According to the exemplary embodiments of the present invention, the edge gate insulating layer pattern disposed under an edge portion of the gate electrode is thicker than the central gate insulating layer pattern disposed on the lower central portion of the gate electrode while applying the STI process, thereby alleviating the electric field concentrated on the lower edge portion of the gate electrode to inhibit a leakage current. Additionally, the edge gate insulating layer pattern and the central gate insulating layer of the exemplary embodiments of the invention can be readily fabricated using depositing and etching techniques used during the manufacturing of a semiconductor device.

### BRIEF DESCRIPTION OF THE DRAWINGS

FIG. 1 is a layout of a conventional MOS transistor;

FIG. 2 is a sectional view of the conventional MOS transistor taken along line A-A′ of FIG. 1;

FIG. 3 is a layout of a MOSFET according to an exemplary embodiment of the present invention; and

FIGS. 4 through 10 are sectional views illustrating a process of fabricating the MOSFET according to an exemplary embodiment of the present invention.

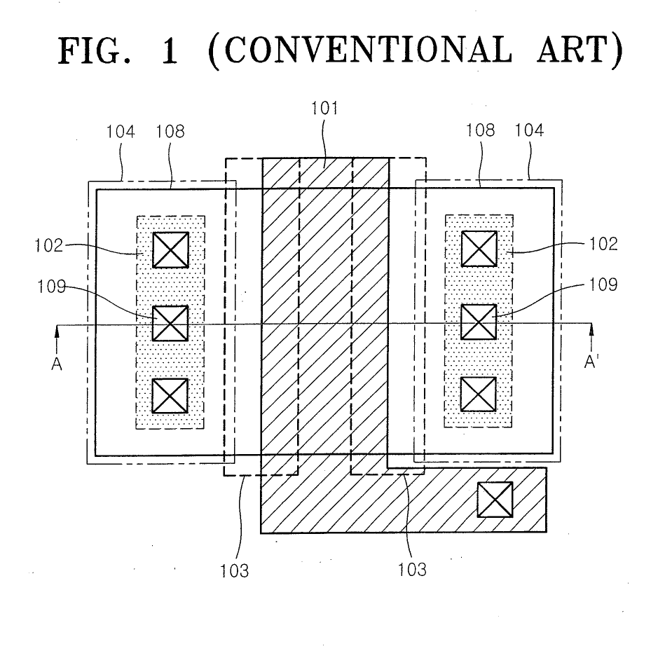

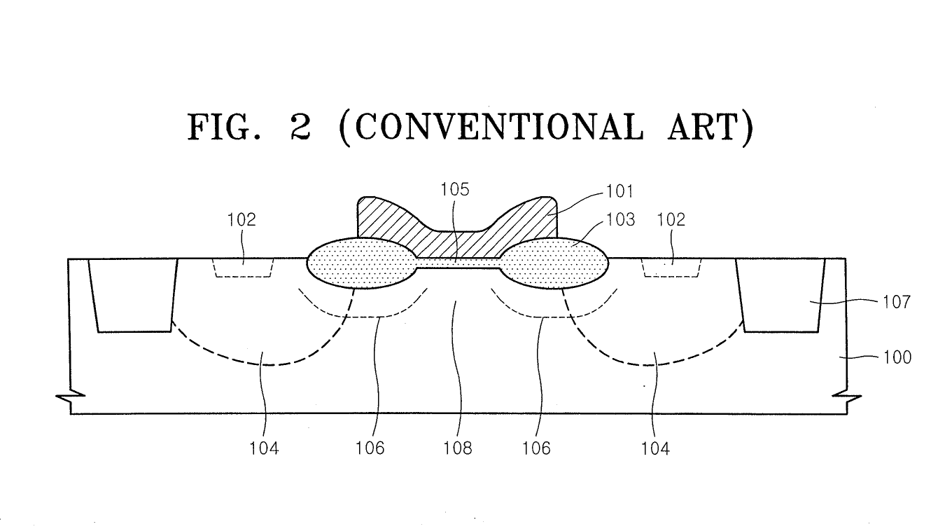

### DETAILED DESCRIPTION OF THE EXEMPLARY EMBODIMENTS OF THE INVENTION

The present invention will now be described more fully with reference to the accompanying drawings, in which exemplary embodiments of the invention are shown.

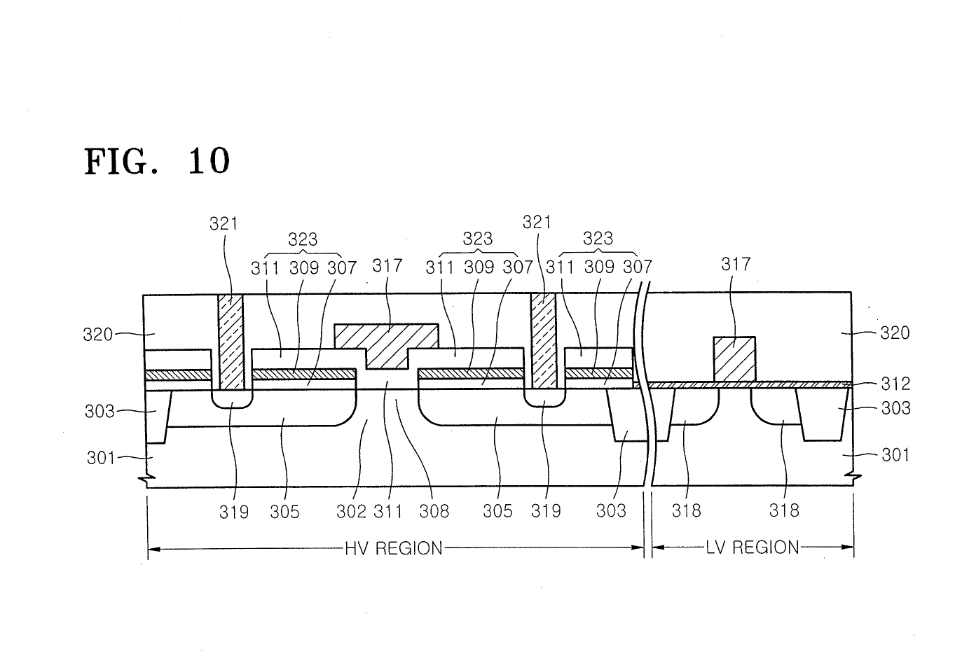

FIG. 10 shows a structure of a MOSFET according to an exemplary embodiment of the present invention, in which the left portion is a high voltage (HV) region formed with a high voltage transistor and the right portion is a low voltage (LV) region formed with a low voltage transistor. For example, in LDI-related products, a high voltage transistor for driving an LCD device is formed in the HV region, and a low voltage transistor for logic may be formed on the LV region. The exemplary embodiments of the present invention is not limited to the LDI structure, but may be applied to semiconductor devices with various types as long as a high voltage transistor is formed at least in the HV region.

Referring to FIG. 10, in the HV region, a trench-shaped device isolating region 303 is disposed in a predetermined portion of a semiconductor substrate 301 composed of, e.g., single crystalline silicon. The trench-shaped device isolating layer 303 defines an active region 302 where a transistor is operated. A gate electrode 317 is disposed on an upper portion of the active region 302. First source/drain regions 305 are formed within the active region 302 and under both sides of the gate electrode 317.

Edge gate insulating layer patterns 323 each obtained by stacking a first gate insulating layer 307, a second gate insulating layer 309, a third gate insulating layer 311 are respectively interposed between respective first source/drain regions 305 and the gate electrode 317. The edge gate insulating layer patterns 323 may cross over the first source/drain regions 305 to extend under the edge portion of the gate electrode 317 to the device isolating region 303 to define the active region 302. A channel region 308 is formed around an upper surface of the active region 302 underlying the gate electrode 317.

A central gate insulating layer in single layer form is interposed between the channel region 308 and the gate electrode 317 and extends from the third gate insulating layer 311. The edge gate insulating layer pattern 323 formed on the lower edge portion of the gate electrode 317 is thicker than the third gate insulating layer 311 that is a central gate insulating layer formed under the central portion of the gate electrode 317. Also, the bottom of the edge gate insulating layer pattern 323 and the third gate insulating layer 311 are levelled with a surface of the semiconductor substrate 301. Here, the edge gate insulating layer pattern 323 is thick to have an upper surface higher than an upper surface of the third gate insulating layer 311.

The first source/drain regions 305 constitute relatively low density regions, and high density regions 319 implanted with an impurity ion with a density higher than those of the first source/drain regions 305 are partially formed, thereby defining a Double Diffused Drain (DDD) structure. At this time, the high density regions 319 are formed at locations where source/drain contacts 321 are formed by opening contact holes after forming an interlayer insulating layer 320 during a subsequent process, thus securing ohmic contacts.

Moreover, in the LV region, a device isolating region 303 that defines a predetermined active region is formed on the semiconductor substrate 301 similar to the HV region. Then, second source/drain regions 318 spaced apart from each other are formed within the active region 302, and a fourth gate insulating layer 312 is formed on the channel region interposed between the second source/drain regions 318, so that the gate electrode 317 is formed on the channel region. In contrast to the HV region, a low voltage transistor is formed on the LV region. Accordingly, although a thickness of a fourth gate insulating layer 312 acting as a gate insulating layer is identical or substantially identical under the edge portion or the central portion of the gate electrode 317, the electric field concentration under the edge portion of the gate electrode 317 causes no significant difficulties.

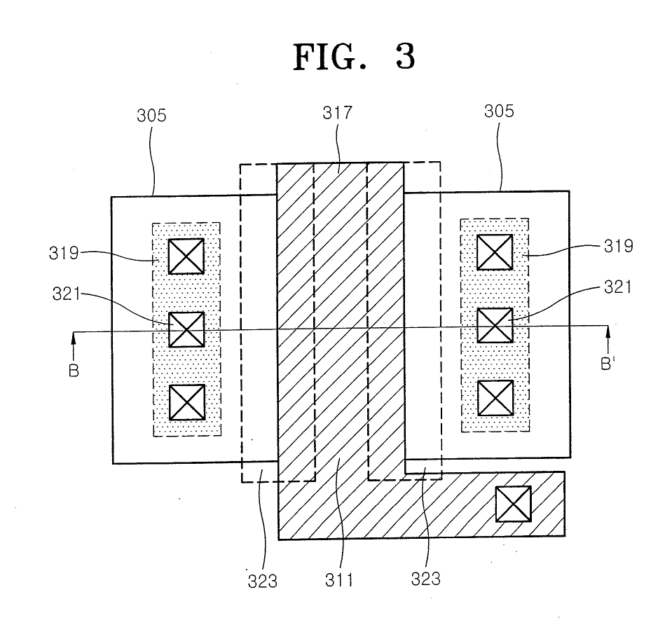

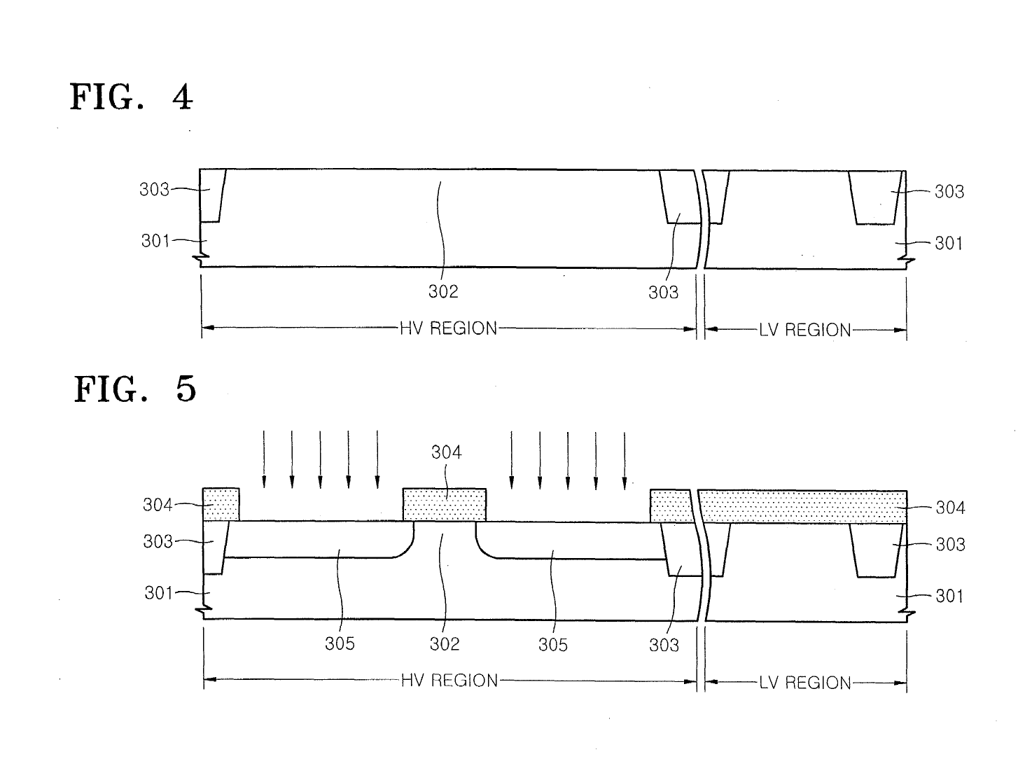

Thereafter, referring to FIGS. 3 through 10, a method of fabricating the MOSFET according to an exemplary embodiment of the present invention will be described. FIG. 3 is a layout of the MOSFET, and the HV region shown in the left portion in FIGS. 4 through 10 is obtained by taking a line B-B′ of FIG. 3. In FIGS. 4 through 10, the HV region adjacently corresponds to the LV region for conveniently comparing the processing steps. The HV region denotes a first active region where a HV transistor will be formed, and the LV region denotes a second active region where a LV transistor will be formed.

Referring to FIGS. 3 and 4, for example, the device isolating region 303 with the STI structure is formed on a predetermined region of the semiconductor substrate 301 composed of, e.g., single-crystalline silicon. The trench-type device isolating region 303 defines the active region 302. The device isolation region 303 is formed using STI, in which a buffer oxide layer and an oxidation-preventing layer are first formed on the entire or substantially the entire surface of the semiconductor substrate 301. At this time, the buffer oxide layer may be composed of a thermal oxide layer, and the oxidation-preventing layer may be composed of a silicon nitride layer. Subsequently, a photoresist pattern is formed on the oxidation-preventing layer. The photoresist pattern covers an upper portion of the active region 302, and exposes a region that will be the device isolating region 303.

Thereafter, using the photoresist pattern or the oxidation-preventing layer as an etch mask, at least the oxidation-preventing layer and the buffer oxide layer are etched to form a buffer oxide layer pattern and an oxidation-preventing pattern subsequently stacked. The stacked buffer oxide layer pattern and the oxidation-preventing layer pattern cover the active region 302 and expose the portion where the device isolating region will be formed. Then, the semiconductor substrate 301 with an exposed portion where the device isolating region will be formed is etched to form a trench. The inside of the trench is then filled with an insulating layer, thereby forming the trench-type device isolating region 303. Here, the device isolating region 303 may be formed on both HV and LV regions to define the active regions of the HV region that is the first active region formed with the HV transistor and the LV region that is the second active region formed with the LV transistor.

Referring to FIG. 5, photolithography is performed to form an ion implanting mask 304, e.g., a photoresist mask, a silicon oxide layer mask or a silicon oxide layer mask, on the entire or substantially the entire surface of the semiconductor substrate 301. Subsequently, ion implantation is carried out with a low density to form the source/drain regions 305 within the active region 302 of the HV region. The source/drain regions 305 are diffusion layers of low density, which are formed by implanting an ion typically using phosphorous impurities with a density of about 2.0E12 to about 5.0E123 at an energy of about 150 KeV to about 300 KeV. At this point, the LV region is covered with the ion implanting mask 304 so as to be unaffected by ion implanting.

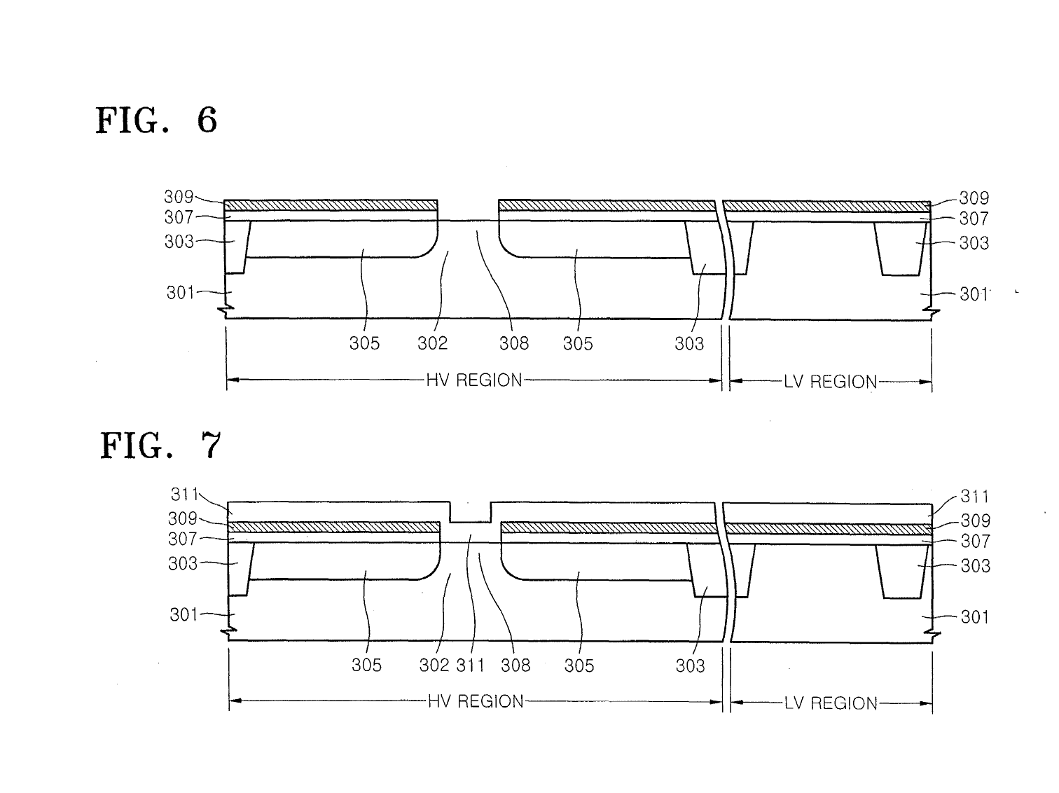

Referring to FIG. 6, after removing the ion implanting mask 304, the first insulating layer 307 and the second insulating layer 309 are sequentially stacked on the entire or substantially the entire surface of the semiconductor substrate 301. The first insulating layer 307 is composed of, e.g., an oxide layer. When stacking the oxide layer, CVD is used to form the oxide layer to have a thickness of about 50 Å to about 500 angstroms (Å), and may be about 100 Å to about 200 Å. Thereafter, the second insulating layer 309 is formed using CVD to have a thickness of about 50 Å to about 500 Å, and may be about 100 Åto about 200 Å. The second insulating layer 309 may be composed of diverse materials, e.g., a nitride layer class such as a silicon nitride layer and a metal oxide layer class such as alumina or tantalum. Then, the first insulating layer 307 and the second insulating layer 309 are removed using photolithography to expose a portion of the semiconductor substrate 301 where the channel region 308 is disposed between the source/drain regions 305.

Referring to FIG. 7, the third insulating layer 311 is stacked on the entire surface of the resultant structure. The third insulating layer 311 is composed of, e.g., an oxide layer. The oxide layer is stacked using CVD to have a thickness of about 200 Å to about 2000 Å, and may be about 500 Å to about 700 Å. The third insulating layer 311 on the portion to be the channel region 308 acts as the central gate insulating layer under the central portion of the gate electrode (317 in FIG. 9) formed in a subsequent process. Then, the triple insulating layer comprising the first insulating layer 307, the second insulating layer 309, and the third insulating layer 311 stacked on both sides of the channel region 308 to overlap the source/drain regions 305 acts as an insulating layer for preventing a GIDL, thereby functioning as a field transistor under the edge portion of the gate electrode 317.

The triple structure comprising the oxide layer/nitride layer/oxide layer has the same structure as a layer acting as a dielectric film formed between upper and lower conductive layers formed when a capacitor of the semiconductor device is formed. Accordingly, the triple layer may be effectively used even though a fabricating process of a field transistor is not additionally performed during fabricating a semiconductor transistor that requires a capacitor. Generally, a high voltage transistor and a capacitor are used together in an LCD panel driving chip. If the dielectric film with the triple structure of the oxide layer/the nitride layer/the oxide layer is applied when performing the aforementioned process, it simplifies the fabrication process. Such a capacitor may be formed on both the HV region and the LV region.

The edge gate insulating layer disposed on the lower edge portion of the gate electrode 317 has the triple layer structure comprising the first insulating layer 307, the second insulating layer 309, and the third insulating layer 311 in this exemplary embodiment. However, the edge gate insulating layer may alternatively have a double layer structure by taking into consideration the etch selectivity between the insulating layers. For example, an oxide layer/an oxide layer structure may be used.

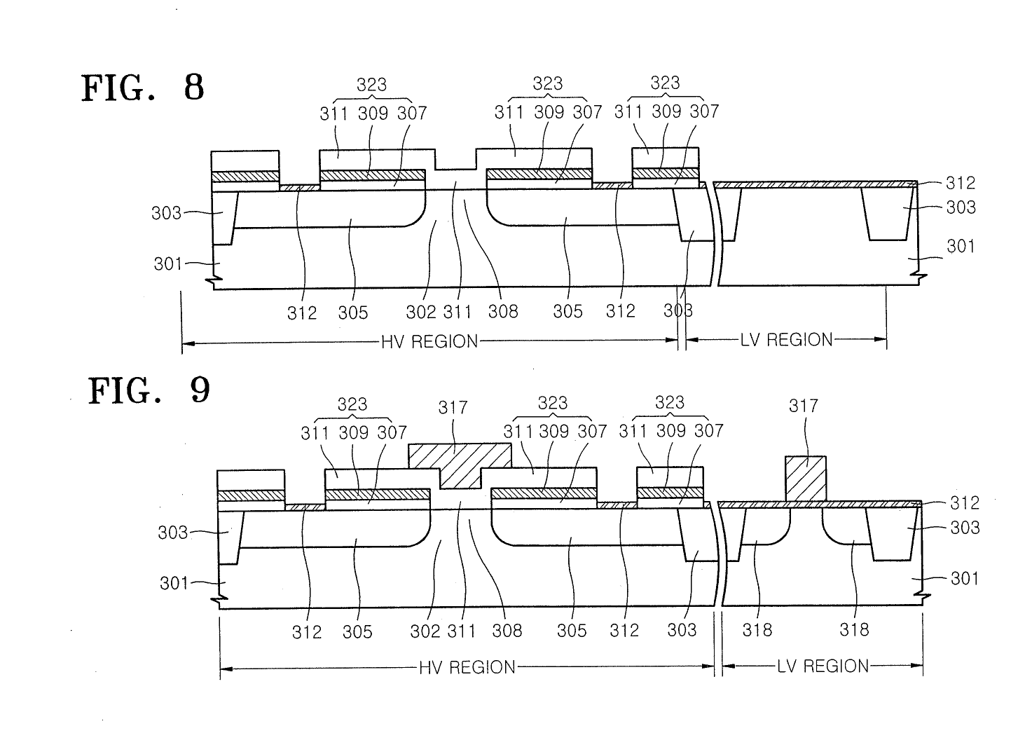

Referring to FIG. 8, the triple layer structure comprising the first insulating layer 307, the second insulating layer 309, the third insulating layer 311 is etched to form a relatively thin gate insulating layer in the LV region provided on a peripheral portion of the semiconductor substrate 301. At this point, the triple layer on the source/drain regions 305 within the HV region is partially etched together. The portion where the triple layer is removed will be filled with the source/drain contacts in a subsequent process. Thus, the portion becomes a high density region implanted with an impurity ion with a relatively high density as compared with the source/drain regions 305 with a relatively low density. In addition, the portion may be etched simultaneously with the etching of the triple layer for forming the gate insulating layer of the low voltage transistor within the LV region without requiring additional etching by separately forming a pattern for implanting the impurity ion.

Subsequently, the fourth insulating layer 312 is formed on the surface of the semiconductor substrate 301 exposed by etching the triple layer. The fourth insulating layer 312 is formed using e.g. thermal oxidation or CVD to a sufficient thickness for use as a gate insulating layer of the low voltage transistor in the LV region. Simultaneously, the fourth insulating layer 312 is formed on the surface of the semiconductor substrate 301 on which the high density region will be formed within the HV region. Therefore, the fourth insulating layer 312 can sufficiently act as a buffer layer for preventing damage upon the semiconductor substrate 301 when a conductive layer for forming the gate electrode 317 is subsequently etched.

Referring to FIG. 9, the conductive layer is stacked on the resultant structure, and is patterned to form the gate electrode 317. The conductive layer for the gate electrode 317 is, e.g., a polysilicon layer. Simultaneously with forming the gate electrode 317 in the HV region, the gate electrode 317 for the low voltage transistor is formed in the LV region. As described above, the fourth insulating layer 312 formed on the portion which will be the high density region within the HV region shields the surface of the semiconductor substrate 301 when etching is taking place to form the gate electrode 317.

After forming the gate electrode 317, ion implanting is performed in the LV region to form the second source/drain regions 318 within the semiconductor substrate 301 under both sidewalls of the gate electrode 317.

Again referring to FIG. 10, the impurity ion with a high density is implanted into the first source/drain regions 305 within the HV region, thereby forming the high density region 319. The high density region 319 may be formed together with forming the second source/drain regions 318 within the LV region. The high density region 319 may be formed by ion implanting at an energy of about 40 KeV to aobut 60 KeV using, e.g., Arsenic with a density of about 5.0E14 to about 5.0E16.

Then, the fourth insulating layer 312 remaining on the high density region 319 is removed, and the thick interlayer insulating layer 320 composed of, e.g., an oxide layer, is formed on the entire or substantially the entire surface of the semiconductor substrate 301. Thereafter, contact holes for the source/drain contacts are formed, and filled with a conductive material, thereby forming the source/drain contacts 321. In addition, the source/drain contacts may be simultaneously formed in the LV region.

According to the exemplary embodiments of the present invention, a thick gate insulating layer is formed under an edge portion of a gate electrode, thereby preventing GIDL caused by an electric field concentrated on that portion. Furthermore, the exemplary embodiments of the invention provide a semiconductor device suitable for diverse voltage conditions, by allowing for diverse thick gate insulating layers to be readily formed by patterning a multi-layered insulating layer even in a STI structure. These diverse thick gate insulating layers may be formed using various materials, thicknesses and lengths. Moreover, with the present exemplary embodiments, the gate insulating layer is thick under an edge portion of a gate electrode to reinforce a withstand voltage characteristic but, a central gate insulating layer is thinner than a conventional layer under a central portion of the gate electrode where a channel region is formed. Consequently, as a result of the above, on-resistance is decreased and the performance of the device is enhanced, which in turn decreases dispersion of the threshold voltage and chip size to embody a competitive semiconductor device. Furthermore, the thickness of the edge gate insulating layer is controlled to readily form a high pressure transistor of about 20 to about 50V. At the same time, a low pressure transistor for logic formed on a peripheral portion can be readily formed.

While the present invention has been particularly shown and described with reference to exemplary embodiments thereof, it will be understood by those of ordinary skill in the art that various changes in form and details may be made therein without departing from the spirit and scope of the present invention as defined by the appended claims.

What is claimed is:

1. A method of fabricating a Metal Oxide Semiconductor Field-Effect Transistor (MOSFET) comprising:
forming a device isolating region in a predetermined portion of a semiconductor substrate to define an active region;
forming a source region and a drain region spaced apart from each other within the active region;
forming a first insulating layer pattern for exposing a channel region disposed between the source region and the drain region;
forming a second insulating layer on at least substantially an entire surface of the semiconductor substrate having the first insulating layer pattern thereon; and
forming a gate electrode overlapping at least part of the source region and the drain region stacked with the first insulating layer pattern and the second insulating layer, and wherein said gate electrode also overlaps at least part of the channel region formed with the second insulating layer thereon.

2. The method of claim 1, wherein the device isolating region has a trench structure.

3. The method of claim 1, wherein the first insulating layer pattern comprises a plurality of layers.

4. The method of claim 3, wherein an uppermost layer of the first insulating layer pattern and the second insulating layer are composed of the same material.

5. The method of claim 3, wherein the first insulating layer pattern is composed of a lower oxide layer and an intermediary insulating layer.

6. The method of claim 5, wherein the intermediary insulating layer is composed of at least one layer selected from a group consisting of a nitride layer, an aluminum oxide layer and a tantalum oxide layer.

7. The method of claim 1, further comprising: before forming the gate electrode,
partially removing the first insulating layer pattern and the second insulating layer to expose a surface of the semiconductor substrate; and
forming a third insulating layer on the exposed surface of the semiconductor substrate.

8. The method of claim 7, further comprising: after forming the gate electrode,
forming high density regions with an ion density higher than those of the source region and the drain region within a portion of the semiconductor substrate.

9. A method of fabricating a Metal Oxide Semiconductor Field-Effect Transistor (MOSFET) comprising:
forming a device isolating region in a predetermined portion of a semiconductor substrate for defining a first active region formed with a high voltage transistor and a second active region formed with a low voltage transistor;
forming a first source region and a first drain region spaced apart from each other within the first active region;
forming a first insulating layer on at least substantially an entire surface of the semiconductor substrate, and etching the first insulating layer to form a first insulating layer pattern that exposes a channel region disposed between the first source region and the first drain region;
forming a second insulating layer on at least substantially an entire surface of the semiconductor substrate formed with the first insulating layer pattern thereon;
removing the first insulating layer pattern and the second insulating layer formed on the second active region; and
forming a gate electrode material on the entire surface of the semiconductor substrate, and etching the gate electrode material to form a first gate electrode that overlaps at least part of the first source region and the first drain region stacked with the first insulating layer pattern and the second insulating layer, and wherein said gate electrode also overlaps at least part of the channel region formed with the second insulating layer thereon.

10. The method of claim 9, wherein the first insulating layer comprises a plurality of layers.

11. The method of claim 10, wherein an uppermost layer of the first insulating layer pattern and the second insulating layer are composed of the same material.

12. The method of claim 9, further comprising: when removing the first insulating layer pattern and the second insulating layer formed on the second active region,
partially removing the first insulating layer pattern and the second insulating layer within the first active region to expose a surface of the semiconductor substrate; and
before forming the first gate electrode, forming a third insulating layer on the surface of the exposed semiconductor substrate.

13. The method of claim 12, comprising: when forming the first gate electrode, forming a second gate electrode on the third insulating layer formed on the second active region.

14. The method of claim 13, further comprising: after forming the second gate electrode, forming a second source region and a second drain region within the semiconductor substrate under both sides of the second gate electrode.

15. The method of claim 1, wherein the forming the source region and the drain region comprises:
forming an ion implanting mask on the semiconductor substrate;
performing an ion implantation within the active region to form the source region and the drain region; and
removing the ion implanting mask.

16. The method of claim 9, wherein the forming the first source region and the first drain region comprises:
forming an ion implanting mask covering the second active region on the semiconductor substrate;
performing an ion implantation within the first active region to form the first source region and the first drain region; and
removing the ion implanting mask.
